(19) United States
(12) Patent Application Publication
(10) Pub. No.: US 2022/0343378 A1
(43) Pub. Date: Oct. 27, 2022

(54) QUOTATION SYSTEM, QUOTATION METHOD, AND QUOTATION PROGRAM

(71) Applicant: MISUMI CORPORATION, Tokyo (JP)

(72) Inventors: Kenta OWA, Tokyo (JP); Tomoaki YOKOTA, Tokyo (JP)

(73) Assignee: MISUMI CORPORATION, Tokyo (JP)

(21) Appl. No.: 17/760,876

(22) PCT Filed: Feb. 10, 2021
(86) PCT No.: PCT/JP2021/004994

§ 371 Date: Mar. 16, 2022

(30) Foreign Application Priority Data
May 26, 2020 (JP) 2020-091634

(51) Int. Cl. G06Q 30/02

(52) U.S. Cl. CPC G06Q 30/0283

(57) ABSTRACT

A quotation system receives shape data of an article configured from a plurality of elements from a client terminal and provides quotation information of the article. The system has a memory for storing basic shape data and related shape data different from the basic shape data, and storing basic attribute information associated with a basic element of the basic shape data. The system also has a computer that is configured to acquire the basic shape data and the related shape data, determine whether the relationship between the related shape data and the basic shape data satisfies a predetermined condition, associate related attribute information, including information common to the basic attribute information, and store the related attribute information, and prepare quotation information of an article corresponding to the related shape data on the basis of the related shape data and the related attribute information stored in the memory.

### CROSS-REFERENCE TO RELATED PATENT APPLICATIONS

This application is a U.S. National Phase Application under 35 U.S.C. § 371 of International Patent Application No. PCT/JP2021/004994 filed on Feb. 10, 2021 and claims the benefit of priority to Japanese Patent Applications No. 2020-091634 filed on May 26, 2020, the contents of all of which are incorporated herein by reference in their entireties. The International Application was published in Japanese on Dec. 2, 2021 as International Publication No. WO2021/240906 under PCT Article 21(2).

### FIELD OF THE INVENTION

The present invention relates to a quotation system, quotation method, and quotation program that take on attribute information.

### BACKGROUND OF THE INVENTION

JP 2016-062403 A discloses an automatic quotation system. In this automatic quotation system, a shape recognition processing unit recognizes the shape of an item described in shape data input by a user. Then, a display information processing unit acquires manufacturing conditions that can be selected on the basis of the type of item input by the user and the recognized shape of the item. Furthermore, a display processing unit displays the general shape of the recognized item on an item shape display part in a display screen and displays the manufacturing conditions on a manufacturing condition selection part. The user selects any manufacturing condition from among the manufacturing conditions displayed on the manufacturing condition selection part. Then, the user selects a quotation start part displayed on a display unit to cause the automatic quotation system to initiate quotation processing.

### CITATION LIST

### Patent Literature

[Patent Literature 1] JP 2016-062403 A

### Technical Problem

In a conventional system, when basic shape data, such as 3D CAD data, of an article is changed, a user uploads related shape data after the basic shape data has been changed to the system. At this time, the user must reset the attribute information (for example, attribute information such as tolerance), which is set in the basic shape data before the change, for the related shape data. Furthermore, when the user uploads the related shape data similar to shape data uploaded in the past, the user must reset the attribute information for the related shape data.

Therefore, as a consequence of processing to reset the attribute information being necessary, the processing time required for design processing accompanying quotation becomes longer. Moreover, because the user manually inputs the attribute information, there is also a possibility that an error may occur where the input of attribute information to the related shape data is accidentally omitted.

### SUMMARY OF THE INVENTION

### Solution to Problem

A quotation system according to one aspect of the present invention is the quotation system which receives shape data of an article configured from a plurality of elements from a client terminal and which provides quotation information of the article, and the quotation system comprising: storage means storing basic shape data and related shape data different from the basic shape data, and storing basic attribute information associated with at least one basic element of the basic shape data; data acquisition means acquiring the basic shape data and the related shape data; determination means determining whether the relationship between the related shape data and the basic shape data satisfies a predetermined condition; association means, when the predetermined condition is satisfied, associating related attribute information, which includes common information that is common to the basic attribute information, with at least one related element of the related shape data, and storing the related attribute information in the storage means; and quotation means preparing quotation information of an article corresponding to the related shape data on the basis of the related shape data and the related attribute information which are stored in the storage means.

Furthermore, a quotation method according to one aspect of the present invention is the quotation method in a quotation system which receives shape data of an article configured from a plurality of elements from a client terminal, which provides quotation information of the article, and which has a computer, the quotation method comprising: storing basic shape data and related shape data different from the basic shape data, and storing basic attribute information associated with at least one basic element of the basic shape data; acquiring the basic shape data and the related shape data; determining whether the relationship between the related shape data and the basic shape data satisfies a predetermined condition; associating, when the predetermined condition is satisfied, related attribute information, which includes common information that is common to the basic attribute information, with at least one related element of the related shape data, and storing the related attribute information; and preparing quotation information of an article corresponding to the related shape data on the basis of the related shape data and the related attribute information which are stored.

Furthermore, a quotation program, according to one aspect of the present invention, is the quotation program of a quotation system which receives shape data of an article configured from a plurality of elements from a client terminal, which provides quotation information of the article, and which has storage means storing basic shape data and related shape data that is different from the basic shape data and storing basic attribute information associated with at least one basic element of the basic shape data, and which has a computer, wherein the quotation program causes the computer to function as: data acquisition means acquiring the basic shape data and the related shape data; determination means determining whether the relationship between the related shape data and the basic shape data satisfies a predetermined condition; association means, when the predetermined condition is satisfied, associating related attribute information, which includes common information that is common to the basic attribute information, with at least one related element of the related shape data, and storing the related attribute information in the storage means; and quotation means preparing quotation information of an article corresponding to the related shape data on the basis of the related shape data and the related attribute information which are stored in the storage means.

As above, according to the present invention, it is possible to take on attribute information set in shape data, and the processing time required for design processing accompanying the quotation of an article may be shortened. Furthermore, according to the present invention, the occurrence of errors accompanying the setting of attribute information may be suppressed.

### BRIEF DESCRIPTION OF THE DRAWINGS

FIG. 1 is a schematic configuration diagram of an entire quotation system.

FIG. 2 is a descriptive diagram of an article corresponding to basic shape data.

FIG. 3 is a diagram illustrating one example of a basic information view.

FIG. 4 is a diagram illustrating one example of a quotation screen.

FIG. 5 is a schematic block diagram of the entire quotation system.

FIG. 6 is a flow chart of processing in a first embodiment.

FIG. 7 is a descriptive diagram of an article corresponding to related shape data.

FIG. 8 is a diagram illustrating one example of an upload screen.

FIG. 9 is a descriptive diagram of an article corresponding to related shape data.

FIG. 10 is a descriptive diagram of an article according to a second embodiment.

FIG. 11 is an explanatory diagram of a mirror article according to the second embodiment.

### DETAILED DESCRIPTION OF THE INVENTION

Exemplary embodiments for implementing the present invention will be described in detail below with reference to drawings. However, the dimensions, material, shape, and relative positions of constituent elements described in the embodiments below may be set freely, and may be changed according to the configuration of a device to which the present invention is applied or various conditions. Furthermore, unless otherwise stated, the scope of the present invention is not limited to the embodiments specifically described below.

### First Embodiment

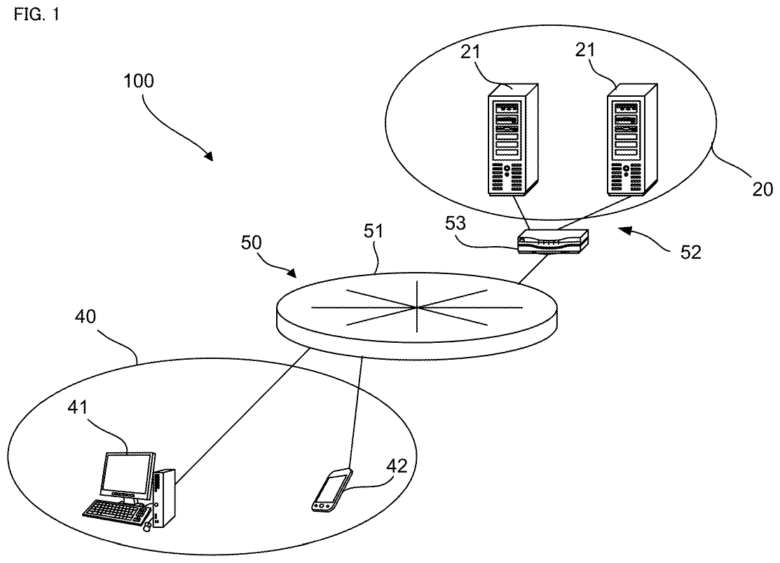

FIG. 1 illustrates a quotation system 100 used for quotation of the price of an article configured from a plurality of elements. The quotation system 100 receives shape data of an article from a client terminal 40 and provides quotation information of the article. For example, a server 20 of the quotation system 100 receives and stores shape data transmitted from the client terminal 40 by a user. As one example, an element is a portion constituting an article such as a hole, axis, step, notch, corner, plane, or ridge line and includes a shape obtained by machining. Furthermore, the shape data is 3D CAD data that includes the shape of the article and may include information such as the dimensions and position of each element. Note that the shape data is data that includes the shape of the article, and may be 2D CAD data.

Attribute information such as tolerance and dimensions required for each element is associated with the shape data. The attribute information includes first tolerance information relating to a tolerance with respect to a distance between the elements and second tolerance information relating to a tolerance with respect to a dimension within the elements. Furthermore, the attribute information may be included in the shape data, and the shape data and the attribute information may be different data. When the shape data and the attribute information are different data, for example, a table including attribute information associated with an element of the article is used.

The first tolerance information includes a tolerance of a distance from an origin to an element with reference to the origin set in the shape data. Furthermore, the first tolerance information includes a tolerance of a distance between a certain element and another element. Furthermore, the first tolerance information includes a tolerance of distance of an element to a geometric reference, for example, a tolerance of a machining position. Moreover, the first tolerance information includes, as another example, a tolerance of a distance from the geometric reference to the central axis of the element, for example, coaxiality or concentricity. Furthermore, the first tolerance information includes information identifying a subject constituting a geometric reference.

The second tolerance information is, as one example, a tolerance with respect to the size of the element, for example, a hole diameter, an axis diameter, width, length, depth, or outer diameter. Specifically, the second tolerance information includes a tolerance zone class relating to the element.

In addition, the attribute information is information that indicates a customer order number, quantity, material, surface processing, content of comments (additional instructions), type of hole (hole type), hole diameter tolerance, effective depth (full thread length), slot width tolerance, external dimension tolerance, design origin, holes of the same group (group hole division), appearance plane (plane constituting the appearance of the article), font size (such as the dimensional notation), geometric tolerance, datum (reference for geometric tolerance), surface roughness, and the like, and includes various kinds of information used in quotation and subsequent manufacturing. Then, the attribute information includes information associated with an element of the article and information associated with the shape data.

Information such as the dimensions and position of each element and attribute information may be set in the CAD software of the client terminal 40. Furthermore, the quotation system 100 may be configured so that information such as the dimensions and position of each element and the attribute information may be set on a screen provided by the server 20.

The article (item) may be a finished product in which the article itself has one collective function, or may be one component incorporated into the finished product, or may be an assembly composed of a plurality of components. Moreover, the article includes a unit, a jig, a device, and equipment combining a plurality of components. Furthermore, holes of the same group are, for example, a plurality of holes that exist on the same plane and have the same diameter and depth. However, holes from among the same group of holes may be divided into different groups for each type of hole, and in the present specification, information indicating that they belong to divided groups is referred to as “group hole division”. Furthermore, types of holes include, as one example, drill holes, tap holes, holes that require high precision for fitting (hereinafter also referred to as precision holes), and the like.

The quotation system 100 is configured as a network system provided with the server 20 as a quotation server or as a client server system. The server 20 functions as a server device and is constituted as one logical server device by combining, for example, server units 21 as a plurality of computers. However, the server 20 may be constituted by a single server unit 21. Alternatively, the server 20 may be logically configured using cloud computing. The server 20 provides various kinds of services including an article quotation service to the client terminal 40 or to the user of the client terminal 40. These services include a distribution service for distributing a program or data to the client terminal 40 through a network 50 and a storage service for storing the data received from the client terminal 40. The distribution service is, for example, a service for distributing data for updating.

The client terminal 40 is a computer device capable of network connection. For example, the client terminal 40 includes a desktop or laptop type personal computer 41, a portable tablet terminal device 42, or like. In addition, a mobile terminal device such as a mobile phone (including a smart phone) is included as the client terminal 40. The client terminal 40 allows the user to enjoy various services provided by the server 20 by installing various kinds of computer software. Furthermore, the client terminal 40 may be connected to the server 20 through the predetermined network 50. Below, a case will be described where the client terminal 40 is the personal computer 41.

The network 50 is configured to be able to connect each client terminal 40 to the server 20. As one example, the network 50 is configured to realize network communication by using TCP/IP protocol. Specifically, a LAN (local area network) 52 connects the server 20 and an internet 51. Then, the internet 51 as a WAN (wide area network) and the LAN 52 are connected via a router 53. The client terminal 40 is also configured to be connected to the internet 51. The server units 21 of the server 20 may be mutually connected by the internet 51 in place of or in addition to the LAN 52.

The server 20 guides the user through various kinds of procedures required for the user to quote the price of the article via the client terminal 40. That is, the server 20 functions as a web server that causes the display unit (display device 46, described below) of the client terminal 40 to display various kinds of web pages according to access from the client terminal 40 by a control of the server control unit 22, described below. Furthermore, the server 20 may execute processing such as the arrangement of ordered articles, delivery instructions, and billing of the purchase price corresponding to an order by the user.

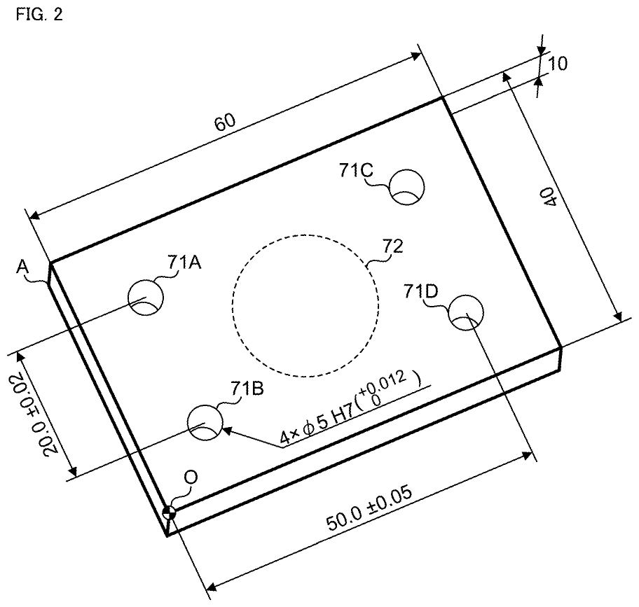

An outline of the present invention will be described with reference to FIG. 2 to FIG. 4. Note that FIG. 2 illustrates previously uploaded basic shape data, and a hole 72 added by adding a change to the basic shape data is virtually illustrated by a dashed line. Furthermore, an article A corresponding to the basic shape data includes four precision holes 71A to 71D. In the example in FIG. 2, various kinds of attribute information are set for the basic shape data.

Specifically, a tolerance zone class “H7” is set as second tolerance information and a hole diameter “φ5” is set as a dimension for the precision holes 71A to 71D. Furthermore, a distance between centers of 20.0 mm of the precision hole 71A and the precision hole 71B is set, and plus/minus of 0.02 mm is set as first tolerance information of the distance between centers. Moreover, a distance of 50.0 mm on a long side relative to a design origin O as a reference and plus/minus of 0.05 mm as first tolerance information are set for the precision hole 71D. Furthermore, a dimension of 60 mm in the Y direction, a dimension of 40 mm in the X direction, and a dimension of 10 mm in the Z direction are set as external dimensions of the article A.

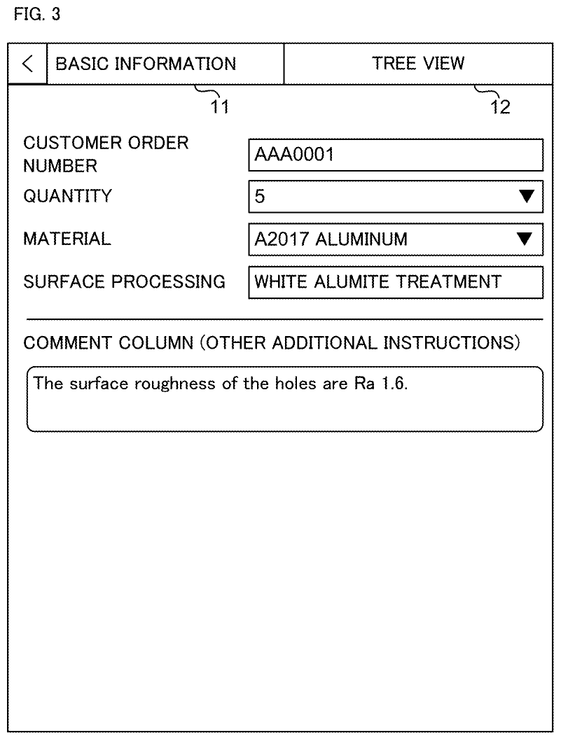

FIG. 3 is one example of a basic information view displayed on the display unit (display device 46, described below) of the client terminal 40. As illustrated in FIG. 3, the attribute information set in the basic shape data corresponding to the article A includes basic information associated with the basic shape data. The basic information view of FIG. 3 includes a basic information tab 11 and a tree view tab 12. Then, the (customer) order number, purchase quantity, material, content of the surface processing, and additional instructions (comments input by the customer) are displayed in the basic information view of FIG. 3 that is displayed by selecting the basic information tab 11. That is, as basic information, an order number “AAA0001”, a purchase quantity of five pieces, the surface processing type “white alumite treatment”, and “aluminum” that is the material of the article A, and a code “A2107” thereof defined by the JIS Standards are set in the basic shape data. Moreover, the basic information includes using “Ra 1.6,” which is the arithmetic average roughness, as the surface roughness of an inner plane of the precision holes 71A to 71D. Note that the material may be set only by a code, abbreviation, or common name in accordance with the JIS Standards, ISO Standards, DIN Standards, AISI Standards, or the like. Furthermore, other basic information may also be set by an abbreviation, common name, or code. For example, the type of surface processing may be simply set to “white alumite”.

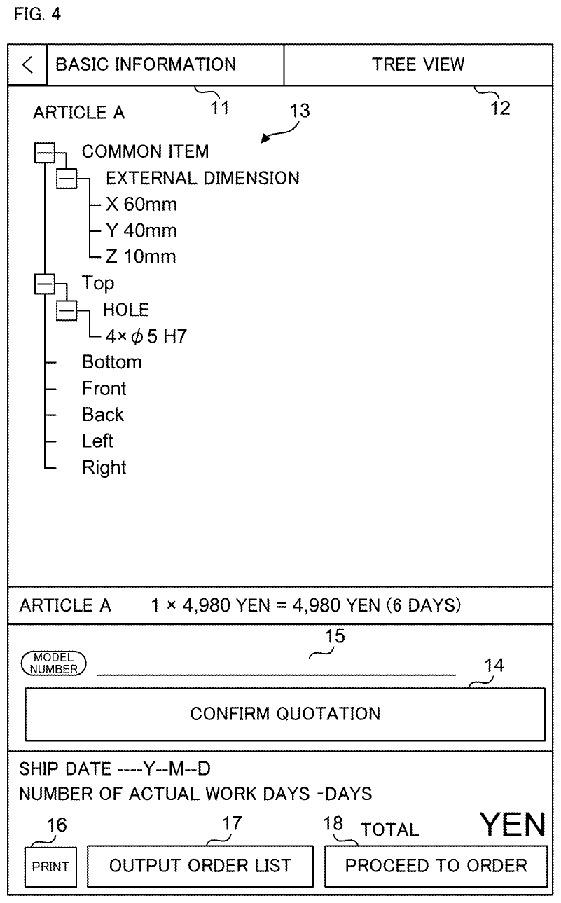

FIG. 4 is one example of a quotation screen displayed on the display unit (display device 46, described below) of the client terminal 40. As displayed on the quotation screen illustrated in FIG. 4, the quotation screen also includes the basic information tab 11 and the tree view tab 12. Then, in the basic information view of FIG. 3, when the tree view tab 12 is selected, a tree view 13 such as that illustrated in FIG. 4 is displayed. In the tree view 13, for example, an external dimension of the article and machining contents of each plane (upper plane, bottom plane, front plane, back plane, left plane, and right plane) of the article are displayed.

In the example in FIG. 4, a dimension of “60 mm” in the X direction, a dimension of “40 mm” in the Y direction, and a dimension of “10 mm” in the Z direction are displayed as information illustrating the external dimensions of the article A. Furthermore, “4×φ5 H7” is displayed as information illustrating that a hole having a hole diameter of “φ5”, wherein the tolerance zone class “H7” is set, is machined in four locations on an upper plane (top) of the article A. Furthermore, “4,980 yen” is displayed as a quoted price of one article A. Moreover, “6 days” is displayed as the number of actual work days required until shipment.

Moreover, a confirm button 14 for quotation is displayed at a lower portion of the quotation screen, and when the user selects the confirm button 14, a total monetary amount, a ship date, and a number of actual work days required until shipment are displayed below the confirm button 14. At this time, a monetary amount obtained by multiplying the price of the article by the purchase quantity is displayed on the quotation screen as the total monetary amount. Moreover, a model number corresponding to the displayed article is displayed in a model number section 15. Furthermore, a print button 16 is displayed below the confirm button 14, and the quotation result may be printed when the user selects the print button 16. Moreover, an output button 17 of an order list and an order button 18 are displayed in parallel to the print button 16.

When the user selects the output button 17, the electronic data of the order list may be output. Furthermore, when the user selects the order button 18, an order screen (not illustrated) for performing an order is displayed by the display unit (display device 46 described below) of the client terminal 40. The user may order an article identified by a model number on the order screen. When the user orders an article, the server 20 transmits the identified model number and the purchase quantity to the manufacturer of the article. Moreover, the server 20 may execute processing for transmitting a delivery instruction for an article to the manufacturer and processing for billing the user for the purchase price. Alternatively, when the user selects the order button 18 on the quotation screen, the server 20 may transmit the identified model number and the purchase quantity to the manufacturer of the article without causing a further operation screen to be displayed.

Here, when making a change to the basic shape data, for example, when adding a new hole 72 as illustrated in FIG. 2, using the client terminal 40, the user prepares related shape data wherein the new hole 72 is added. Then, conventionally, the user sets all attribute information in the related shape data by referencing the basic shape data. Therefore, the user is required to input attribute information, which is a cause of prolonged design work. Furthermore, because the user performs input, there is also a possibility that an error may occur, such as input omission or an input mistake.

Therefore, when related shape data that is different from the basic shape data is uploaded, the quotation system 100 according to the first embodiment causes the related shape data to take on at least one portion of the basic attribute information of the basic shape data. In this manner, because the quotation system 100 causes the attribute information to be taken on, the time required for the setting processing may be reduced, and the design work may be shortened. Furthermore, since the quotation system 100 causes the attribute information to be taken on, the possibility that an error may occur, such as input omission or an input mistake by the user, may be reduced.

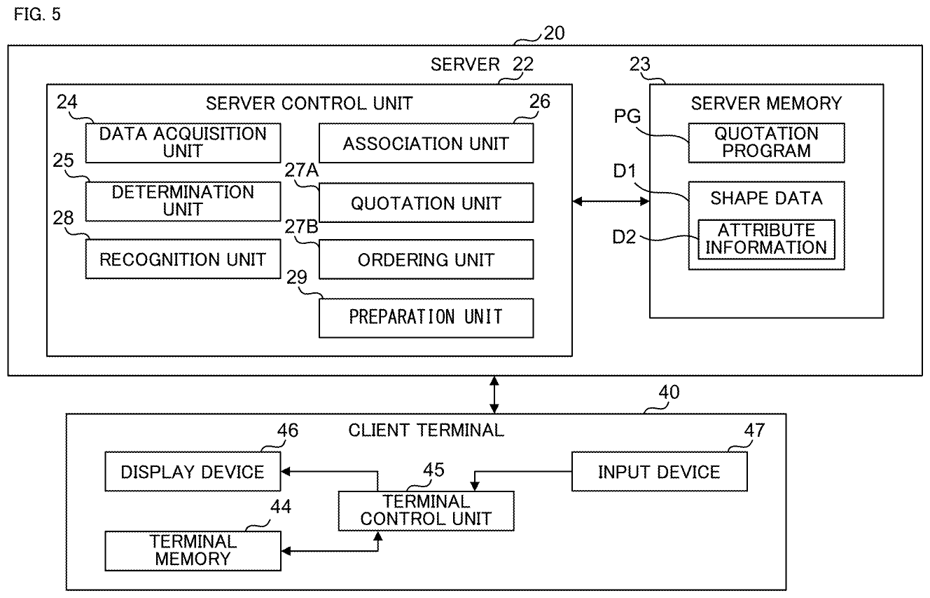

Next, a schematic configuration of a control system of the quotation system 100 will be described with reference to FIG. 5. The server 20 is provided with a server control unit 22 as control means and a server memory 23 as storage means. The server control unit 22 is configured as a computer that combines a processor for executing various kinds of arithmetic processing and operation control according to a predetermined program, internal memory necessary for the operation of the processor, and other peripheral devices. The processor is, for example, a CPU (Central Processing Unit) or an MPU (Micro-Processing Unit), and it controls the entire device on the basis of a control program stored in the server memory 23 and also provides overall control regarding various kinds of processing. Moreover, the server control unit 22 executes various kinds of processing accompanying the quotation of the price of an article on the basis of a quotation program PG stored in the server memory 23.

The server memory 23 includes RAM (Random Access Memory), which is system work memory for the processor to operate, and a storage device such as ROM (Read Only Memory), an HDD (Hard Disk Drive), and an SSD (Solid State Drive) for storing the program and system software. However, the server memory 23 is not limited to the example provided as one portion of the server 20, and may be provided as a database server that cooperates with the server 20. In the present embodiment, a CPU executes processing operations such as various calculations, controls, distinctions, and the like according to a control program stored in the ROM or HDD.

Furthermore, the server memory 23 stores shape data D1 and attribute information D2 of an article. The shape data D1 includes basic shape data and related shape data. Note that the shape data D1 may be uploaded by the user and may be stored in advance by the server memory 23. For example, the user may upload the basic shape data and then later re-upload the related shape data wherein the user has changed the basic shape data. Moreover, the server memory 23 stores in advance basic shape data constituting a sample, and the user may upload the related shape data wherein the basic shape data has been changed.

The attribute information D2 includes basic attribute information associated with at least one basic element of the basic shape data. As one example, the basic attribute information is stored in the server memory 23 as one portion of the basic shape data. Furthermore, the attribute information D2 includes related attribute information associated with at least one related element of the related shape data, and common information, which is information that is common between the basic attribute information and the related attribute information. Moreover, the attribute information D2 includes basic information associated with the basic shape data.

As one example, the basic attribute information includes a tolerance zone class, a hole diameter, a distance between centers, a hole type (type of hole), and first tolerance information which are associated with a hole, which is an element, and respective dimensions associated with a long side, a short side, and a height, which are elements. Furthermore, the related attribute information includes a tolerance zone class, a hole diameter, a distance between centers, a hole type (type of hole), and first tolerance information which are associated with a hole corresponding to a hole of the basic shape data, and respective dimensions associated with a long side, a short side, and a height of the basic shape data. Moreover, the basic information includes an order number, a purchase quantity, a material, and a type of surface processing which are associated with the basic shape data.

Note that the related attribute information includes common information that is common to at least one portion of the basic attribute information. For example, when four precision holes of the basic shape data are reduced to three precision holes in the related shape data, the related attribute information includes, as common information, the tolerance zone class and the hole diameter of each precision hole. On the other hand, the related attribute information does not include information indicating that the number of precision holes is “four”, but includes information indicating that the number of precision holes is “three” as new attribute information. Furthermore, when the hole diameter of a precision hole of the basic shape data is changed in the related shape data, the related attribute information includes the tolerance zone class of each precision hole as common information. On the other hand, the related attribute information does not include the original hole diameter, but includes the changed hole diameter as new attribute information.

In the example in FIG. 5, the attribute information D2 is included in the shape data D1. Specifically, the basic attribute information is included in the basic shape data, and the related attribute information is included in the related shape data. Moreover, the basic information is included in both the basic shape data and the related shape data. Alternatively, the server memory 23 may store the attribute information D2 connected to the shape data D1 as data different from the shape data D1. As one example, the server memory 23 may store the attribute information D2 in the form of a table or list wherein each element of the shape data D1 is associated with various kinds of information.

Furthermore, an operation unit, not illustrated, including a keyboard or various kinds of switches for inputting predetermined commands and data is wired or wirelessly connected to the server control unit 22. Furthermore, a display unit, not illustrated, that displays the input state, setting state, measurement result, and various kinds of information of the server device is wired or wirelessly connected to the server control unit 22. Note that the server control unit 22 is also capable of performing control according to a program stored in a portable recording medium, such as a CD (Compact Disc), a DVD (Digital Versatile Disc), a CF (Compact Flash) card, and a USB (Universal Serial Bus) memory, or an external storage medium, such as a cloud server on the Internet.

The quotation program PG causes the computer to function as a data acquisition unit 24 that is data acquisition means, a determination unit 25 that is determination means, an association unit 26 that is association means, a quotation unit 27A that is quotation means, an ordering unit 27B that is ordering means, a recognition unit 28 that is recognition means, and a preparation unit 29 that is preparation means. That is, the server control unit 22 includes the data acquisition unit 24, the determination unit 25, the association unit 26, the quotation unit 27A, the ordering unit 27B, the recognition unit 28, and the preparation unit 29 as a logical device that is realized by combining computer hardware and software. The quotation program PG may be stored in a computer-readable non-transitory storage medium.

Note that in addition to the foregoing logical device, the server control unit 22 has a logical device and the like, not illustrated, that controls switching and the like of the display of a web page on the display device 46 of the client terminal 40 according to an operation of the client terminal 40. Furthermore, the server memory 23 records various kinds of data, not illustrated, such as image data used for displaying a web page on the display device 46 of the client terminal 40, data including information such as the model number, name, characteristic, or the like of a product or an article, and the like.

The data acquisition unit 24 acquires the basic shape data and the related shape data from the server memory 23. As one example, the server control unit 22 receives the basic shape data from the client terminal 40 in accordance with an upload by the user. Then, the server control unit 22 stores the basic shape data uploaded by the user in the server memory 23. Thereafter, the server control unit 22 receives the related shape data from the client terminal 40 in accordance with a re-upload by the user. Then, the server control unit 22 stores the related shape data uploaded by the user in the server memory 23. Alternatively, the data acquisition unit 24 may acquire the basic shape data and the related shape data from a terminal memory 44 of the client terminal 40.

Furthermore, the data acquisition unit 24 acquires the related shape data in connection with the basic shape data. As one example, the data acquisition unit 24 acquires related shape data in connection with the basic shape data, which is selected when the user uploads the related shape data. Alternatively, the data acquisition unit 24 may compare the file name or order number of the uploaded related shape data to the file name or order number of the basic shape data stored in the server memory 23. In this case, when both file names or both order numbers are similar, the data acquisition unit 24 acquires the related shape data in connection with the basic shape data.

The determination unit 25 determines whether the relationship between the related shape data and the basic shape data satisfies a predetermined condition. Specifically, when the recognition unit 28 recognizes that at least one element of the related shape data and at least one element of the basic shape data are similar, the determination unit 25 determines that the relationship satisfies a predetermined condition.

When the determination unit 25 determines that the predetermined condition is satisfied, the association unit 26 associates related attribute information, including common information that is common to the basic attribute information of the basic shape data, with at least one related element of the related shape data and stores the related attribute information in the server memory 23. For example, when the hole diameter and position of a hole of the related shape data match the hole diameter and position of a hole of the basic shape data, the recognition unit 28 concludes that these holes are similar. In this case, the determination unit 25 determines that the relationship between the related shape data and the basic shape data satisfies a predetermined condition. Then, the association unit 26 associates the second tolerance information of the hole of the basic shape data with the hole of the related shape data and stores the second tolerance information in the server memory 23.

Furthermore, the association unit 26 stores the related attribute information associated with the related element in the server memory 23 as one portion of the related shape data. The related attribute information associated with the related element by the association unit 26 is made by the server control unit 22 to be displayed together with an article image corresponding to the related shape data on the display device 46 of the client terminal 40. Note that the association unit 26 may associate the common information with a plurality of related elements. As one example, the association unit 26 may associate second tolerance information set for one hole of the basic shape data with each of a plurality of holes of the related shape data and include the second tolerance information in each related attribute information.

Moreover, while the details will be described below, when the related shape data includes new attribute information associated with the related element, the association unit 26 does not associate the common information with the related element even when predetermined condition is satisfied. For example, when the second tolerance information is set as new attribute information for a hole of the related shape data, the association unit 26 leaves the second tolerance information unchanged. That is, the association unit 26 leaves the new attribute information associated with the related element as is without replacing it with the second tolerance information set for the basic element. Thus, when the user sets the new attribute information for the related element, the new attribute information may be prevented from being unintentionally changed. In this case, the server control unit 22 may cause the display device 46 to display a selection button for selecting whether to replace the new attribute information with the basic attribute information.

Furthermore, when the determination unit 25 determines that the predetermined condition is satisfied, the association unit 26 associates the basic information associated with the basic shape data with the related shape data and stores the basic information in the server memory 23. For example, the association unit 26 associates the order number, purchase quantity, material, and type of surface processing set in the basic shape data and the content of an additional instruction with the related shape data. Thus, it is possible for the related shape data to take on the basic information, and the processing time required for design processing accompanying the quotation of an article may be shortened. Furthermore, it is possible to suppress the occurrence of errors accompanying the setting of the basic information.

A quotation unit 27A prepares quotation information of an article corresponding to the related shape data on the basis of the related shape data and the related attribute information which are stored in the server memory 23. The quotation information includes at least one from among information on the price of an article and information on the delivery date of the article. Furthermore, the information on the delivery date includes the time of delivery of the goods to the user and the number of actual work days required until shipment. As one example, the quotation unit 27A prepares a monetary amount obtained by multiplying the purchase quantity acquired from the server memory 23 by the price of the article and the number of actual work days required until shipment as quotation information of the article corresponding to the related shape data. In addition, the quotation unit 27A prepares a quotation screen for presenting quotation information. This quotation screen is displayed on the display device 46 of the client terminal 40, and the quotation system 100 thereby provides the quotation information of the article to the user of the client terminal 40.

The ordering unit 27B performs order processing of an article corresponding to the shape data D1, for example, an article corresponding to the related shape data. During order processing, for example, the ordering unit 27B identifies the model number of the article and prepares an order screen as a web page for ordering the article corresponding to the identified model number, and the server control unit 22 causes the display device 46 of the client terminal 40 to display the order screen. Then, when the user orders an article, the ordering unit 27B transmits the identified model number and the purchase quantity to the manufacturer of the article. One example of a quotation screen that is a web page of the previous stage of the order screen is illustrated in FIG. 4.

The recognition unit 28 compares the basic element and the related element and concludes whether the related element and the basic element are similar. As one example, the recognition unit 28 concludes whether the shape of the basic element of the basic shape data and the shape of the related element of the related shape data are similar. Specifically, when the related shape data is uploaded, the recognition unit 28 recognizes coordinates in the XYZ space as the position of the related element and recognizes the dimensions as the shape of the related element. Similarly, the recognition unit 28 recognizes the position and shape of the basic element of the basic shape data. Then, when the position and shape of the related element matches the position and shape of the basic element, it is concluded that both elements are similar. Note that the recognition unit 28 may conclude that both elements are similar when the positions of both elements match. Moreover, the recognition unit 28 may conclude whether the related element and the basic element are similar according to a criterion for similarity determination set by the user. This criteria for similarity determination may be automatically suggested by referencing a history set by the user in the past. As one example, the criteria for similarity determination is criteria for concluding that they are similar when the sizes of the related element and the basic element (for example, diameter of a hole) are the same; criteria for concluding that they are similar when the positions of the related element and the basic element (for example, the position of a hole) are the same; and criteria for concluding that they are similar when the sizes and positions of the related element and the basic element are the same.

Moreover, the recognition unit 28 may conclude that both elements are similar when another property matches, for example, when the color set by the user matches between the related element and the basic element. The user may set different colors for each element in the shape data. Therefore, by comparing the colors of the related element and the basic element, it is possible to conclude whether both elements are similar. Moreover, when the server 20 is provided with a machine learning unit, the recognition unit 28 may conclude whether the related element and the basic element are similar on the basis of data updated using machine learning.

Furthermore, the recognition unit 28 concludes whether all elements included in the related shape data are similar to each element of the basic shape data. Alternatively, the recognition unit 28 may first compare the positions of the related element and the basic element and conclude whether both elements are similar when the positions of both elements are close or match. Moreover, the recognition unit 28 may be configured so that a user is able to set a level of similarity. As one example, the recognition unit 28 may be configured so that the user is able to set either one of two levels: a high level at which it is concluded that they are similar when the positions and shapes of both elements match, and a low level at which it is concluded that they are similar when the positions of both elements match.

The preparation unit 29 prepares, on the basis of the basic shape data, the related shape data of a mirror article having a bilaterally symmetrical shape with respect to the article corresponding to the basic shape data. The preparation unit 29 inverts each element included in the basic shape data to obtain the mirror article.

Moreover, the preparation unit 29 adds an attribute to the prepared related shape data to indicate correspondence to the mirror article and stores the same in the server memory 23. In this case, the preparation unit 29 prepares mirror attribute information indicating that the related shape data corresponds to the mirror article, and the server control unit 22 is capable of causing the display device 46 of the client terminal 40 to display the mirror attribute information together with the article image. As one example, the preparation unit 29 prepares a character string for the “mirror article” as mirror attribute information, and the server control unit 22 causes the display device 46 of the client terminal 40 to display the character string. Alternatively, the preparation unit 29 may prepare mirror attribute information by attaching the letter “M” to one portion of the model number displayed on the screen.

Furthermore, the preparation unit 29 connects the prepared related shape data and the basic shape data, attaches a new file name or a model number to the related shape data, and stores this in the server memory 23. Alternatively, the preparation unit 29 may combine the basic shape data and the related shape data and store them in the server memory 23 as one piece of new shape data.

Next, a configuration of the client terminal 40 will be described. The client terminal 40 is provided with a terminal control unit 45 for controlling the client terminal 40, and the terminal memory 44 wherein the control program is stored. The terminal control unit 45 is a computer that combines a processor for executing various kinds of arithmetic processing and operation control according to a predetermined program, and other peripheral devices. Furthermore, the client terminal 40 is provided with the display device 46 and an input device 47.

As one example, the processor of the terminal control unit 45 is, for example, a CPU or an MPU, and it controls the entire device on the basis of a control program stored in the terminal memory 44 and also provides overall control regarding various kinds of processing. Furthermore, the terminal memory 44 includes RAM, which is system work memory for the processor to operate, and a storage device such as ROM, an HDD, an SSD, and the like for storing the program and system software. In the present embodiment, a CPU executes processing operations such as various calculations, controls, distinctions, and the like according to a control program stored in the ROM or HDD. Furthermore, the terminal control unit 45 is also capable of performing control according to a program stored in a portable recording medium, such as a CD, a DVD, a CF card, and a USB memory, or an external storage medium, such as a cloud server on the Internet.

The terminal memory 44 is an external storage device including a nonvolatile storage medium (computer-readable non-transitory storage medium), such as a hard disk and a semiconductor storage device. Moreover, the terminal memory 44 stores, in addition to the control program, a design program for preparing the shape data D1, such as CAD software, and various kinds of programs, such as a web browser.

The input device 47 is a keyboard, numeric keypad, and touch panel, and the like, and the user prepares or changes the shape data D1 using the input device 47. Then, the shape data D1 prepared using the input device 47 is recorded in the terminal memory 44. Furthermore, when receiving an article image corresponding to the shape data D1 from the server 20, the display device 46 displays the article image. Moreover, the display device 46 displays a web page, such as a setting screen, a quotation screen, and an order screen. The user orders the article according to the web page displayed on the display device 46.

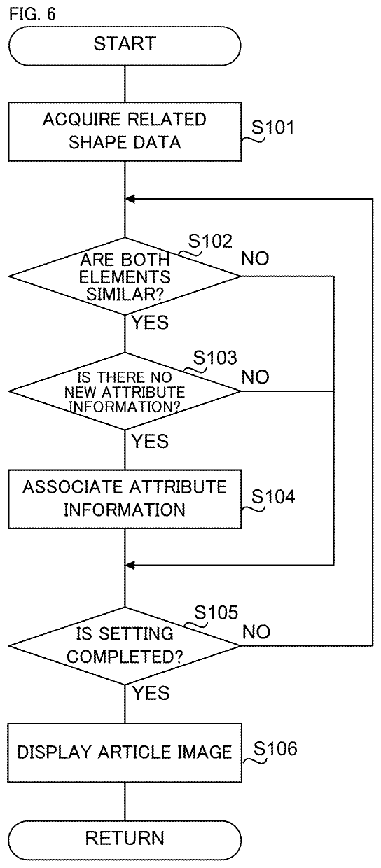

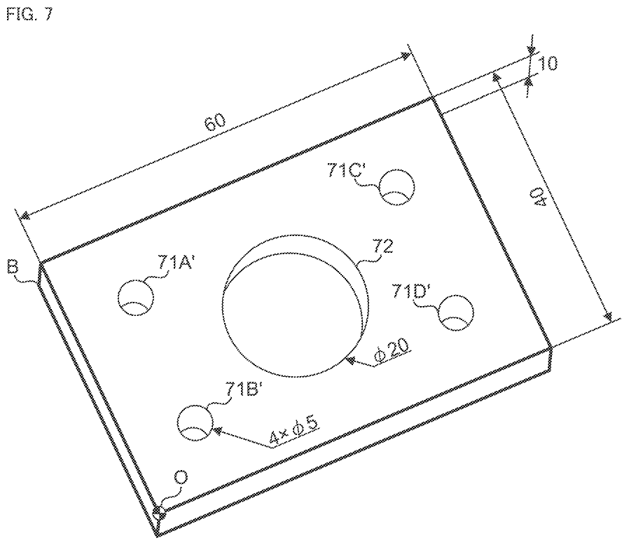

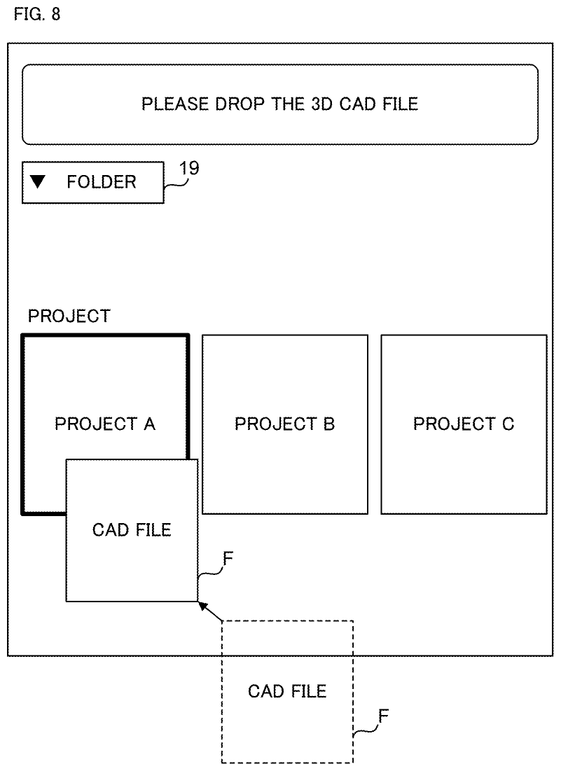

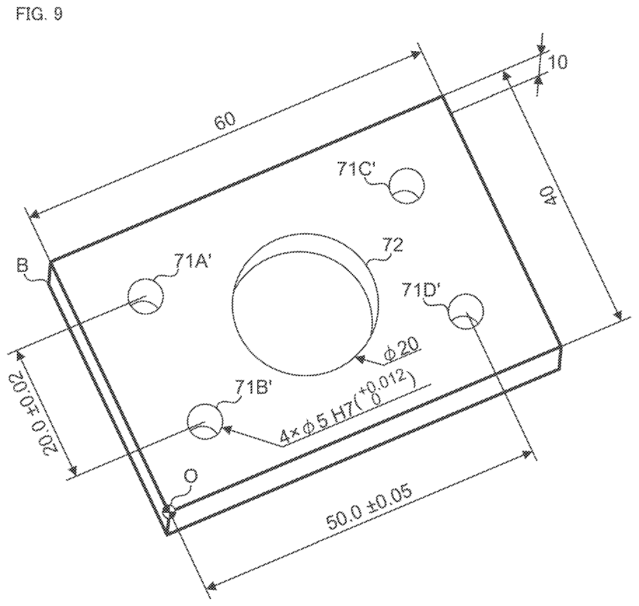

Next, design processing in the first embodiment will be described with reference to FIGS. 6 to 9. Design processing includes all processing performed from upload of the related shape data to order processing. FIG. 6 is a flow chart of design processing, FIG. 7 and FIG. 9 illustrate the article corresponding to the related shape data, and FIG. 8 illustrates one example of an upload screen displayed on the display device 46 of the client terminal 40.

First, the user prepares related shape data on the client terminal 40 on the basis of the basic shape data corresponding to the article A illustrated in FIG. 2. In the first embodiment, the user adds a change to the basic shape data and prepares related shape data corresponding to an article B illustrated in FIG. 7. That is, the user adds the new hole 72 having a hole diameter of 20 mm to the article A. Then, the user accesses a web page provided by the server 20 from the client terminal 40, and uploads the related shape data.

On the upload screen illustrated in FIG. 8, the user moves the icon of a CAD file F, which is the related shape data, and drops it onto the icon of a project corresponding to the basic shape data from among projects A, B, and C. In the example in FIG. 8, the user drops the icon of the CAD file F onto the icon of project A. Thus, the user simultaneously selects the basic shape data to be connected to the related shape data and uploads the related shape data. Then, the server control unit 22 stores the related shape data in the server memory 23. Next, the data acquisition unit 24 acquires the related shape data in connection with the selected basic shape data (S101 in FIG. 6). Furthermore, the user may upload the CAD file F by dropping the icon of the CAD file F in the area, where the character string “Please drop the 3D CAD file” is displayed, above the folder selection button 19 in FIG. 8.

Alternatively, the user may click the folder selection button 19 on the upload screen to select a desired folder in the server 20 and upload the CAD file F into the selected folder. In this case, the data acquisition unit 24 compares the file name of the uploaded CAD file F to the file name of the basic shape data stored in the server memory 23, and when both file names are similar, the CAD file F may be acquired in connection with the basic shape data having a similar file name. Furthermore, the server control unit 22 may suggest basic shape data to be connected to the uploaded related shape data. For example, the server control unit 22 may search for at least one basic shape data that satisfies a similarity condition with respect to the related shape data and automatically suggest it as basic shape data to be connected to the related shape data. The similarity condition is satisfied when the shapes of the related shape data and the basic shape data (for example, the dimensions or coordinates of the elements) are similar, when the file names of the related shape data and the basic shape data are similar, or the like. Furthermore, the server control unit 22 suggests basic shape data at arbitrary timing. As one example, the server control unit 22 automatically suggests the basic shape data immediately after the user uploads the related shape data.

Moreover, the server control unit 22 may display a search box for the basic shape data on the upload screen. In this case, the user searches for and selects the basic shape data to be connected to the uploaded related shape data. Then, the data acquisition unit 24 acquires the uploaded related shape data in connection with the basic shape data, which is searched for and selected by the user. Furthermore, the server control unit 22 may cause a button, which is used for selecting the basic shape data and the related shape data to be mutually connected, to be displayed on a predetermined screen (for example, a setting screen). The data acquisition unit 24 connects and acquires the related shape data and the basic shape data selected by the user. The data acquisition unit 24 acquires the related shape data that is connected with the basic shape data at arbitrary timing. As one example, the data acquisition unit 24 acquires related shape data that is connected with the basic shape data immediately after the user uploads the related shape data.

Next, the recognition unit 28 concludes whether the basic element of the basic shape data and the related element of the related shape data are similar by referencing the connected related shape data and basic shape data (S102 in FIG. 6). When there is no related element similar to the basic element (NO in S102), the attribute information is not taken on. Then, the user inputs and sets the attribute information of the related element. However, even if there is no related element similar to the basic element, the basic information associated with the basic shape data may be taken on by the related shape data.

Thereafter, when the setting of the attribute information for the element that needs to be set is not completed (NO in S105), it is concluded whether another related element is similar (S102). On the other hand, when the attribute information is set for all elements of the related shape data that need to be set (YES in S105), the server control unit 22 causes the display device 46 to display the article image (S106). At this time, the server control unit 22 displays the basic information view or the tree view 13 together with the article image.

When there is a related element similar to the basic element (YES in S102), the determination unit 25 determines that the relationship between the related shape data and the basic shape data satisfies a predetermined condition. Then, when it is determined that the predetermined condition is satisfied, the association unit 26 concludes whether the related shape data includes new attribute information associated with the related element (S103). When there is new attribute information set to the related element (NO in S103), the attribute information corresponding to the new attribute information is not taken on, and the new attribute information set by the user is not changed. However, even when there is new attribute information, the other attribute information not set to the related element and the basic information associated with the basic shape data are taken on by the related shape data. Alternatively, the server control unit 22 may cause the display device 46 to display a selection button for selecting whether to replace the new attribute information of the related element with the basic attribute information of the basic element corresponding to the related element. When the user selects replacement, the attribute information is taken on and the new attribute information is changed to the basic attribute information.

Then, when the attribute information is set for all elements of the related shape data that need to be set (YES in S105), the server control unit 22 causes the display device 46 to display the article image (S106). At this time, the server control unit 22 displays the basic information view or the tree view 13 together with the article image. On the other hand, when the setting of the attribute information for the element that needs to be set is not completed (NO in S105), it is concluded whether another related element is similar (S102). Note that the association unit 26 need not conclude whether there is new attribute information. That is, conclusion processing may be omitted. In this case, even when there is new attribute information, the association unit 26 associates the basic attribute information with the related element instead of the new attribute information.

When there is no new attribute information (YES in S103), the association unit 26 identifies the basic attribute information of the basic element with respect to the related element that is similar to the basic element. Then, the association unit 26 includes at least one portion of the identified basic attribute information in the related attribute information and associates it with a similar related element (S104). Thereafter, the association unit 26 stores the related attribute information in the server memory 23. Moreover, the association unit 26 associates the basic information that is associated with the basic shape data with the related shape data and stores the basic information in the server memory 23. Note that if the association does not need to be limited to only one portion, the association unit 26 associates all of the identified basic attribute information with the related elements. For example, when the basic shape data and the related shape data are the same 3D CAD file, there is no need to limit the association to only one portion.

Specifically, when describing with reference to FIG. 7 and FIG. 9, the recognition unit 28 compares precision holes 71A to 71D in FIG. 2, which are basic elements of the article A, and precision holes 71A′ to 71D′ in FIG. 7, which are related elements of the article B. Here, both precision holes are holes formed in the same position (coordinates), and the hole diameter is “0”. Therefore, the recognition unit 28 recognizes that both precision holes are similar. Then, the determination unit 25 determines that the relationship between the related shape data and the basic shape data satisfies a predetermined condition. Therefore, as illustrated in FIG. 9, the association unit 26 sets the tolerance zone class “H7”, which is the second tolerance information set to precision holes 71A to 71D, to precision holes 71A′ to 71D′.

Furthermore, as illustrated in FIG. 9, the association unit 26 sets information that identifies one of the precision holes 71A and 71B, which are geometric references, as first tolerance information set to the precision holes 71A and 71B, and plus/minus 0.02 mm, as the tolerance of the distance to the geometric references, to precision holes 71A′ and 71B′. Moreover, the association unit 26 sets information that identifies the design origin O, which is a geometric reference, as first tolerance information set to the precision hole 71D, and plus/minus 0.05 mm, as the tolerance of the distance to the geometric reference, to the precision hole 71D′. Note that when necessary, the user may change the first tolerance information and the second tolerance information on the setting screen on which the article B is displayed.

Moreover, the association unit 26 sets the order number, purchase quantity, material, and type of surface processing illustrated in FIG. 3 and the content of an additional instruction to the related shape data as basic information that is set to the basic shape data. Then, when the setting of the attribute information for all elements that need to be set is not completed (NO in S105), it is concluded whether another related element is similar (S102). On the other hand, when the attribute information is set for all elements that need to be set (YES in S105), the server control unit 22 causes the display device 46 to display the article image (S106). At this time, as illustrated in FIG. 9, the server control unit 22 causes the display device 46 to display the second tolerance information, which is related attribute information associated with the related element, and first tolerance information together with the article image of the article B. Furthermore, the server control unit 22 displays the basic information view or the tree view 13 together with the article image.

When the server control unit 22 displays the article image, the design processing is completed. Thereafter, when the user desires a quotation of the article B, the quotation may be performed through the quotation screen. The quotation unit 27A performs quote processing to prepare quotation information of an article corresponding to the related shape data on the basis of the related shape data and the related attribute information which are stored in the server memory 23. Then, the server control unit 22 causes the quotation information to be displayed on the quotation screen. Thereafter, when the user selects the order button 18 on the quotation screen, the ordering unit 27B performs order processing of the article corresponding to the related shape data. Therefore, the server control unit 22 causes the display device 46 to display the order screen prepared by the ordering unit 27B. The user may order the article B on the order screen.

According to the first embodiment described above, attribute information of the basic shape data may be taken on and automatically set to the related shape data. Therefore, it is possible to reduce the time for input processing by the user and to shorten the processing time required for design processing accompanying the quotation of an article. Moreover, since the attribute information is automatically set, the occurrence of errors accompanying the setting of attribute information may be suppressed.

### Second Embodiment

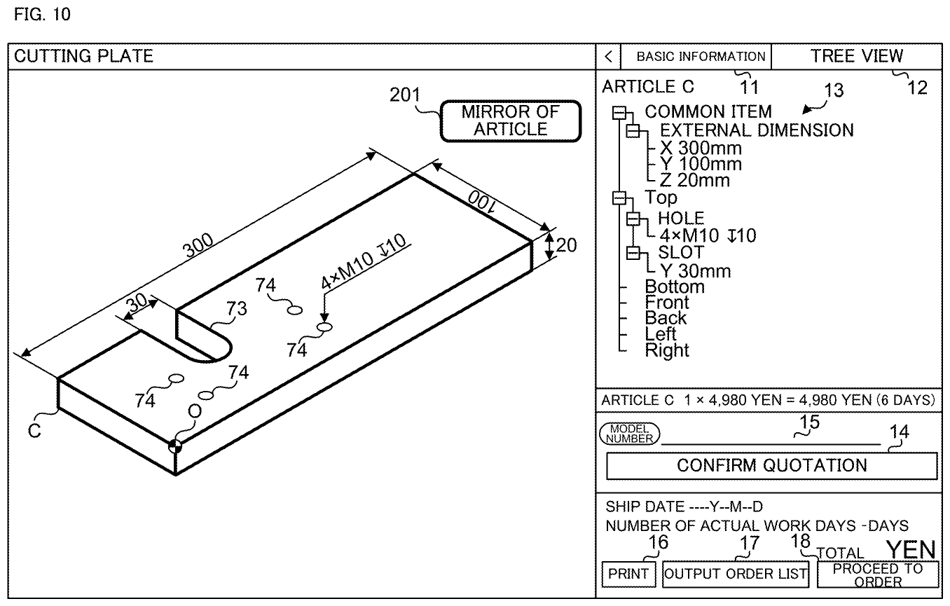

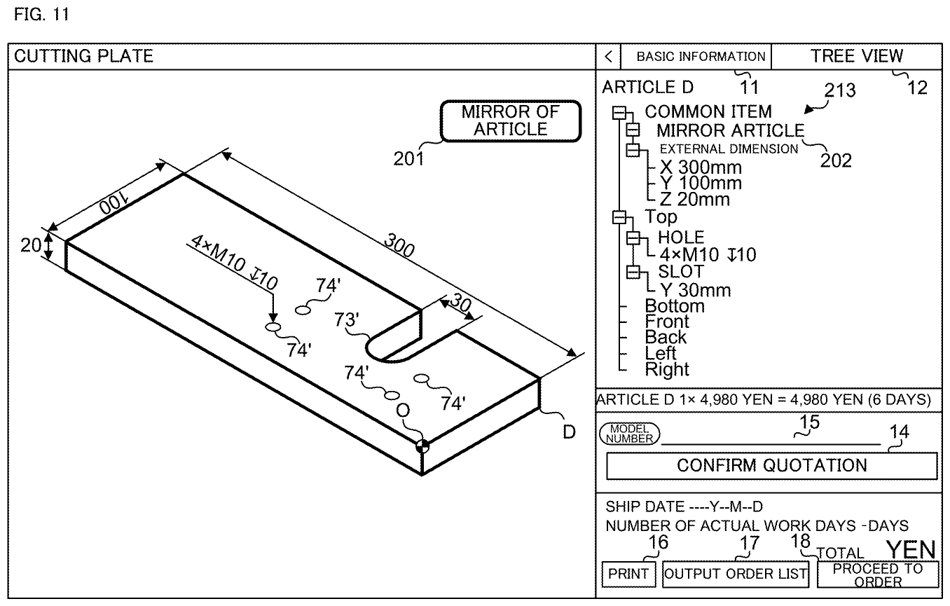

A second embodiment will be described with reference to FIG. 10 and FIG. 11. FIG. 10 and FIG. 11 illustrate one example of a setting screen displayed by the display device 46 of the client terminal 40. The second embodiment differs from the first embodiment in that related shape data corresponds to a mirror article. Note that in the description of the second embodiment, the points that differ from the first embodiment are described, and the constituent elements already described are given the same reference numerals and a description thereof is omitted. Unless otherwise described, the constituent elements to which the same reference numerals are applied perform substantially the same operations and functions, and the operations and effects thereof are substantially the same.

First, as illustrated in FIG. 11, the user prepares the related shape data of a mirror article D having a bilaterally symmetrical shape with respect to an article C on the basis of the basic shape data corresponding to the article C illustrated in FIG. 10. Specifically, a preparation button 201 for a mirror article is provided on the setting screen illustrated in FIG. 10. Then, the user selects the preparation button 201 for a mirror article. When the user selects the preparation button 201, the preparation unit 29 of the server control unit 22 prepares the related shape data corresponding to the mirror article D illustrated in FIG. 11.

That is, the preparation unit 29 prepares the related shape data of the mirror article D on the basis of the basic shape data. Moreover, the preparation unit 29 adds mirror attribute information to the prepared related shape data to indicate correspondence to the mirror article and stores the same in the server memory 23. At this time, the preparation unit 29 stores the prepared related shape data in the server memory 23 in connection with the basic shape data.

Then, the preparation unit 29 prepares mirror attribute information indicating that the related shape data corresponds to the mirror article, and the server control unit 22 causes the display device 46 to display the mirror attribute information together with the article image. As one example, mirror attribute information 202 indicated by the character string “mirror article” is displayed in a tree view 213 of the setting screen illustrated in FIG. 11. Thus, the user is capable of reliably recognizing that the article displayed on the setting screen is a mirror article.

When the preparation unit 29 prepares the related shape data of the mirror article D, the data acquisition unit 24 acquires the related shape data and basic shape data connected to the related shape data. Then, when the related shape data corresponds to the mirror article D, the determination unit 25 determines that the relationship between the related shape data and the basic shape data of the article C satisfies a predetermined condition. Next, the association unit 26 identifies the basic attribute information of the basic element with respect to the related element which is in an inverted position in comparison to the basic element. Then, the association unit 26 includes at least one portion of the identified basic attribute information in the related attribute information and associates it with a related element in an inverted position. Thereafter, the association unit 26 stores the related attribute information in the server memory 23.

When describing with reference to FIG. 10 and FIG. 11, the association unit 26 compares slot 73 and hole 74, which are basic elements of the article C in FIG. 10, to slot 73′ and hole 74′, which are related elements of the mirror article D. Here, the slot 73′ and the hole 74′, when compared to the slot 73 and the hole 74, are at coordinates that are inverted laterally. Therefore, as illustrated in FIG. 11, the association unit 26 sets a width of 30 mm in the Y direction set in the slot 73 to the slot 73′. Moreover, “4×M10” is displayed on the setting screen in FIG. 10 as information illustrating that a tap hole corresponding to “M10” defined by the JIS Standards is machined in four locations on an upper plane (top) of the article C. That is, a tap hole corresponding to “M10” is set to the hole 74 as basic attribute information. Therefore, as illustrated in FIG. 11, the association unit 26 sets the tap hole corresponding to “M10” to the hole 74′.

Furthermore, as illustrated in FIG. 10, a dimension of 300 mm in the X direction, a dimension of 100 mm in the Y direction, and a dimension of 20 mm in the Z direction are set to the article C as external dimensions, which is basic attribute information. Therefore, as illustrated in FIG. 11, the association unit 26 sets the external dimensions to the mirror article D. Moreover, when the basic information is set in the basic shape data, the association unit 26 sets the basic information in the related shape data.

Alternatively, the recognition unit 28 may conclude whether the basic element of the basic shape data corresponding to the article C and the related element of the related shape data corresponding to the mirror article D are similar. In this case, the association unit 26 identifies the basic attribute information of the basic element with respect to the related element that is similar to the basic element. Then, the association unit 26 includes at least one portion of the identified basic attribute information in the related attribute information and associates it with a similar related element. Thereafter, the association unit 26 stores the related attribute information in the server memory 23.

Then, when the attribute information is set for elements of the related shape data that need to be set, the server control unit 22 causes display device 46 to display the article image of the mirror article D, as illustrated in FIG. 11. At this time, the server control unit 22 causes the display device 46 to display related attribute information associated with the related element, together with the article image of the mirror article D. Furthermore, the server control unit 22 causes the basic information view or the tree view 213 to be displayed together with the article image.

When the server control unit 22 causes the article image to be displayed, the design processing is completed. Thereafter, when the user desires a quote of the mirror article D, the quotation may be performed through the quotation screen. Furthermore, when the user selects the order button 18 of the quotation screen, the server control unit 22 causes the display device 46 to display the order screen. The user may order the mirror article D on the order screen.

According to the second embodiment described above, related shape data of the mirror article D may be prepared on the basis of the basic shape data of the original article C. Moreover, attribute information of the basic shape data of the original article C may be taken on and automatically set to the related shape data of the mirror article D. Therefore, it is possible to reduce the time for input processing by the user and to shorten the processing time required for design processing accompanying the quotation of the mirror article D. Moreover, since the attribute information is automatically set, the occurrence of errors accompanying the setting of attribute information may be suppressed.

The present invention was described above with reference to each embodiment, but the present invention is not limited to the embodiments described above. Inventions that have been changed to an extent that does not violate the present invention and inventions equivalent to the present invention are also included in the present invention. Furthermore, each embodiment and each variation may be appropriately combined to an extent that does not conflict with the present invention.

For example, the related shape data is not limited to data different from the basic shape data. As one example, the related shape data may be the same data as the basic shape data, with the exception that the attribute information is not set. That is, the user may upload shape data of the same article as the article corresponding to the basic shape data as related shape data. In this case, even if the attribute information is not set to the related shape data, the attribute information of the basic shape data may be set to the related shape data.

Furthermore, a system provided with the server 20 may be used for applications other than quotation. As one example, a system provided with a server 20 may be used for designing an article. Even in this case, the processing time required for design processing may be shortened, and the occurrence of errors accompanying the setting of attribute information during design may be suppressed.

Moreover, the server control unit 22 may cause an input instruction screen of related attribute information, that is automatically set, to be displayed on the setting screen as a pop up. The user is able to confirm and change the related attribute information on the input instruction screen.

Furthermore, the quotation system 100 may include a client terminal 40. In this case, at least one portion of each means provided to the server control unit 22 may be provided in the terminal control unit 45 of the client terminal 40. As one example, at least one of the data acquisition unit 24, the determination unit 25, the association unit 26, the quotation unit 27A, the ordering unit 27B, the recognition unit 28, and the preparation unit 29 may be provided in the terminal control unit 45. Similarly, at least one portion of each data held by the server memory 23 may be stored in the terminal memory 44 of the client terminal 40.

For example, the client terminal 40 stores the basic shape data and the related shape data input by the user in the terminal memory 44. Then, the data acquisition unit 24 of the terminal control unit 45 acquires the basic shape data and the related shape data from the terminal memory 44. Moreover, the determination unit 25 of the terminal control unit 45 determines whether the relationship between the related shape data and the basic shape data satisfies a predetermined condition. Then, when the predetermined condition is satisfied, the association unit 26 of the terminal control unit 45 associates related attribute information, including information that is common to the basic attribute information of the basic shape data, with at least one related element of the related shape data and stores the related attribute information in the terminal memory 44. In this manner, all processing may be executed on the client terminal 40 side without providing the server 20.

Furthermore, the user may change the shape or dimensions of the article on the web page provided by the server control unit 22. In this case, the server control unit 22 reflects the changes made by the user in the related shape data and stores it in the server memory 23. Then, the data acquisition unit 24 acquires the related shape data, wherein the changes are reflected, from the server memory 23.

Note that the related shape data that is different from the basic shape data includes shape data different from the basic shape data that is uploaded at the same time as the basic shape data. Furthermore, the related shape data different from the basic shape data includes other data whose upload timing is different from that of the basic shape data. In this case, the basic shape data and the related shape data may be the same shape data, with the exception of the upload date and time.

One portion or the entirety of the foregoing embodiments may be described as in the appendix but are not limited thereto.

(Appendix 1)

A quotation system which receives shape data of an article configured from a plurality of elements from a client terminal, the quotation system comprising:

storage means storing basic shape data and related shape data different from the basic shape data, and storing basic attribute information associated with at least one basic element of the basic shape data;

preparation means preparing, on the basis of the basic shape data, the related shape data corresponding to a mirror article having a bilaterally symmetrical shape with respect to the article corresponding to the basic shape data;

association means associating related attribute information, which includes common information that is common to the basic attribute information, with at least one related element of the related shape data, and storing the related attribute information in the storage means; and quotation means preparing quotation information of an article corresponding to the related shape data on the basis of the related shape data and the related attribute information which are stored in the storage means.

### REFERENCE SIGNS LIST

22: Server control unit (computer)
23: Server memory (storage means)
24: Data acquisition unit (data acquisition means)
25: Determination unit (determination means)
26: Association unit (association means)
27A: Quotation unit (quotation means)
27B: Ordering unit (ordering means)
28: Recognition unit (recognition means)
29: Preparation unit (preparation means)
40: Client terminal
46: Display device
71A to D: Precision hole (basic element)
71A′ to D′: Precision hole (related element)
73: Slot (basic element)
73′: Slot (related element)
74: Hole (basic element)
74′: Hole (related element)
100: Quotation system
D1: Shape data
D2: Attribute information
PG: Quotation program

1. A quotation system which receives shape data of an article configured from a plurality of elements from a client terminal and which provides quotation information of the article, the quotation system comprising:
storage means storing basic shape data and related shape data different from the basic shape data, and storing basic attribute information associated with at least one basic element of the basic shape data;
data acquisition means acquiring the basic shape data and the related shape data;
determination means determining whether the relationship between the related shape data and the basic shape data satisfies a predetermined condition;
association means, when the predetermined condition is satisfied, associating related attribute information, which includes common information that is common to the basic attribute information, with at least one related element of the related shape data, and storing the related attribute information in the storage means; and
quotation means preparing quotation information of an article corresponding to the related shape data on the basis of the related shape data and the related attribute information which are stored in the storage means.

2. The quotation system according to claim 1, further comprising recognition means comparing the basic element and the related element and concluding whether the related element and the basic element are similar, wherein
when the recognition means concludes that they are similar, the determination means determines that the relationship satisfies the predetermined condition, and the association means associates the related attribute information with the related element and stores the related attribute information in the storage means.

3. The quotation system according to claim 1, wherein
the basic attribute information is stored in the storage means as one portion of the basic shape data, and
the association means stores the related attribute information associated with the related element in the storage means as one portion of the related shape data.

4. The quotation system according to claim 1, wherein the data acquisition means acquires the related shape data in connection with the basic shape data.

5. The quotation system according to claim 1, wherein when the related shape data includes new attribute information associated with the related element, the association means does not include the common information in the related attribute information even if the predetermined condition is satisfied.

6. The quotation system according to claim 1, wherein the related attribute information associated with the related element by the association means is displayed on a display device of the client terminal together with an article image.

7. The quotation system according to claim 1, further comprising preparation means preparing, on the basis of the basic shape data, the related shape data corresponding to a mirror article having a bilaterally symmetrical shape with respect to the article corresponding to the basic shape data, wherein
the determination means determines that the relationship satisfies the predetermined condition when the related shape data corresponds to the mirror article.

8. The quotation system according to claim 7, wherein the preparation means prepares mirror attribute information indicating that the related shape data corresponds to the mirror article, and the mirror attribute information is displayed on the display device of the client terminal together with an article image corresponding to the associated shape data.

9. The quotation system according to claim 1, further comprising ordering means performing order processing of an article corresponding to the related shape data.

10. The quotation system according to claim 1, wherein the storage means further stores basic information associated with the basic shape data, and
the association means associates the basic information with the related shape data and stores the basic information in the storage means when the predetermined condition is satisfied.

11. A quotation method in a quotation system which receives shape data of an article configured from a plurality of elements from a client terminal, which provides quotation information of the article, and which has a computer, the quotation method comprising:
storing basic shape data and related shape data different from the basic shape data, and storing basic attribute information associated with at least one basic element of the basic shape data;
acquiring the basic shape data and the related shape data;
determining whether the relationship between the related shape data and the basic shape data satisfies a predetermined condition;
associating, when the predetermined condition is satisfied, related attribute information, which includes common information that is common to the basic attribute information, with at least one related element of the related shape data, and storing the related attribute information; and
preparing quotation information of an article corresponding to the related shape data on the basis of the related shape data and the related attribute information which are stored.

12. A quotation program of a quotation system which receives shape data of an article configured from a plurality of elements from a client terminal, which provides quotation information of the article, and which has storage means storing basic shape data and related shape data that is different from the basic shape data and storing basic attribute information associated with at least one basic element of the basic shape data, and which has a computer, wherein
the quotation program causes the computer to function as:
data acquisition means acquiring the basic shape data and the related shape data;
determination means determining whether the relationship between the related shape data and the basic shape data satisfies a predetermined condition;
association means, when the predetermined condition is satisfied, associating related attribute information, which includes common information that is common to the basic attribute information, with at least one related element of the related shape data, and storing the related attribute information in the storage means; and
quotation means preparing quotation information of an article corresponding to the related shape data on the basis of the related shape data and the related attribute information which are stored in the storage means.
